(19) United States
(12) Patent Application Publication
(10) Pub. No.: US 2008/0236738 A1
(43) Pub. Date: Oct. 2, 2008

(54) Bonded sputtering target and methods of manufacture

(76) Inventors: Chi-Fung Lo, Fort Lee, NJ (US); Darryl draper, Congers, NY (US)

Correspondence Address: PRAXAIR, INC.;LAW DEPARTMENT - M1 557, 39 OLD RIDGEBURY ROAD, DANBURY, CT, 06810-5113, US

(21) Appl. No.: 11/731,106

(22) Filed: Mar. 30, 2007

(51) Int. Cl. C23C 14/00; B32B 38/00

(52) U.S. Cl. 156/283; 204/298.12

(57) ABSTRACT

Methods for manufacturing sputtering target assemblies by bonding target materials to backing plates using metals and alloys in powder form to achieve substantially 100% bonding at temperatures achieved in a vacuum hot press.

### FIELD OF THE INVENTION

The present invention is generally directed to methods of manufacturing sputtering target assemblies. More specifically, the present invention is directed to the manufacture of sputter target assemblies comprising powdered layers to assist in bonding layers.

### BACKGROUND OF THE INVENTION

The use of cathodic sputtering as a technique for depositing thin layers of material onto substrates is widely known. This process requires ion bombardment of a target comprising a material that is to be deposited as a thin film onto a particular substrate. The target forms part of a cathode assembly that, together with an electrode, occurs in an evacuated chamber containing an inert gas. A high voltage electric field is then applied. The inert gas is ionized by collision with the electrons ejected from the cathode. Positively charged gas ions are then attracted to the cathode and impinge the target surface, dislodging target material particles. The dislodged target material particles are then deposited as a thin film on the desired substrate located in the chamber, typically near the anode.

Conventionally, in target cathode assemblies, that target is attached to a backing plate. The backing plate may be water-cooled to dissipate heat generated by the sputtering process. The target and backing plate are commonly attached to each other to achieve good thermal and electrical contact. The two components are known to be attached by soldering, brazing, diffusion bonding, clamping, cementing, etc.

Often, the target and backing plate are subjected to considerable, high pressure and heat to effect the desired bond. Known processes have included roughing the target and backing plate surfaces to be joined to between 120 Ra to 150 Ra and otherwise providing relief features to the surfaces (e.g. machining ridges, grooves, etc.) to facilitate bonding. Alternatively, the addition of pre-coated metallic layers have been provided to the bond surface between the target and backing plate surface to be joined, also to facilitate bonding.

A method of providing a strong bond at the sputtering target/backing plate interface with improved processing advantages would be highly advantageous.

### SUMMARY OF THE INVENTION

According to one embodiment, the present invention is directed to a method for manufacturing a sputtering target assembly comprising a metallic backing plate having a first surface and a metallic target material having a first surface. A metallic powder is interposed, in a pre-determined amount, between the first surface of the target material and the first surface of the backing plate to achieve an assembly. The assembly is subjected to a predetermined pressure, predetermined temperature and predetermined holding time adequate to soften the powder and substantially uniformly bond the backing plate to the target material. The bonding temperature is controlled at from about 10° C. to about 100° C. lower than the interlayer powder, such that the softened powder material fills the gaps and voids on both the target and backing plate bonding faces. The assembly is preferably subjected to a vacuum hot press to achieve the required pressure and temperature parameters required to soften the metallic powder and create the desired bonding of the backing plate to the target.

According to a preferred embodiment of the present invention, one or more of the facing target surface and the backing plate surface are roughened to create a surface roughness of from about 150 Ra to about 250 Ra, preferably about 200 Ra.

In one preferred embodiment, the metallic powder is selected from the group consisting of: aluminum metallic powder and aluminum alloy powder; said backing plate is made from aluminum; and the target material is selected from the group consisting of: tungsten, titanium, tantalum, copper, nickel, cobalt, chromium and aluminum.

In a further preferred embodiment, the metallic powder is selected from the group consisting of: copper metallic powder and copper alloy powder; said backing plate is made from copper; and the target material is selected from the group consisting of: tungsten, titanium, tantalum, copper, nickel, cobalt, and chromium.

### BRIEF DESCRIPTION OF THE DRAWINGS

Other objects, features, embodiments and advantages will occur to those skilled in the art from the following description of preferred embodiments and the accompanying drawings, in which:

FIG. 1 is a schematic representation of one embodiment of the present invention;

FIG. 2 is a micro-photograph of a cross-section of a tantalum target with aluminum interlayer made according to one embodiment of the present invention;

FIG. 3 is a micro-photograph of a cross-section of a titanium target bonded to a aluminum with a zinc/aluminum interlayer made according to one embodiment of the present invention; and

FIG. 4 is a micro-photograph of a cross-section of a tantalum target bonded to a copper backing plate with a copper interlayer made according to one embodiment of the present invention.

### DETAILED DESCRIPTION OF THE INVENTION

The present invention is directed to a method of diffusion bonding sputtering targets to backing plates using powders as media to react with the target and backing plate to facilitate their substantially complete (substantially 100%) bonding. While the preferred methods of the present invention use vacuum hot pressing techniques, according to the present invention, significantly less pressure can be used to effect equivalent or improved bonding results compared to known bonding methods. The powder material selected is dependent on the target and backing plate materials. That is, aluminum (Al) powder is selected as the bond medium when bonding tungsten, tantalum, titanium, copper, nickel, cobalt, chromium or aluminum metal or aluminum alloy sputtering plates to aluminum backing plates. Copper powder is preferably used to bond targets made from the above-listed W, Ta, Ti, Cu, Ni, Co, Cr targets, when bonding such targets to a copper metal or copper alloy.

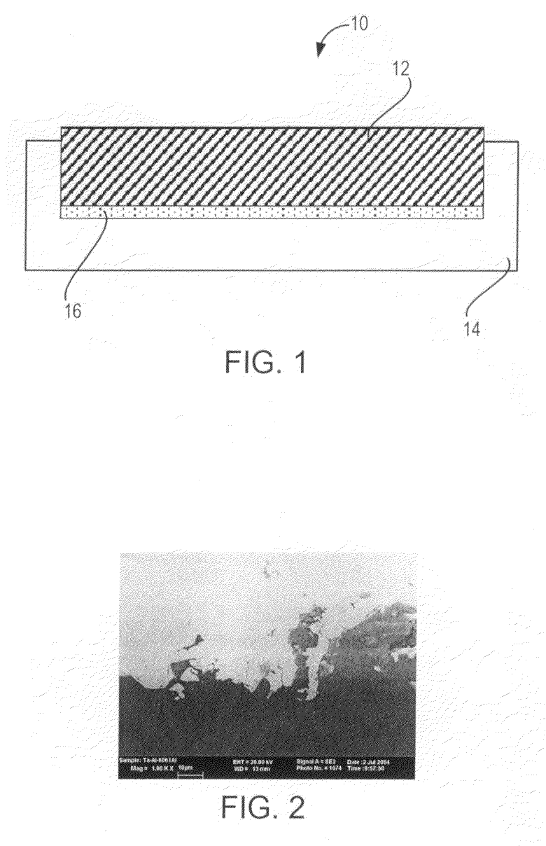

FIG. 1 shows a representative, cross-sectional side view of an embodiment of the present invention where the target assembly 10 comprises a target 12 disposed onto a backing plate 14 with a layer of metallic powder 16 interposed between the target 12 and the backing plate 14.

According to embodiments of the present invention, preferred temperature ranges were established in concert with significantly lower operating pressures, making the methods of the present invention significantly different and more advantageous than the known procedures for adhering targets to their backing plate. More specifically, when using aluminum powder for bonding targets made from the aforementioned metals and alloys to aluminum backing plates, the components are assembled and subjected to temperatures of from about 550° C. to about 650° C. at pressures of only from about 1 to about 2 ksi for a duration of from about 1 to about 5 hours, to achieve a substantially complete bond of about 100%. Similarly, when using copper powder for bonding targets made from the aforementioned metals and alloys to copper backing plates, the components are assembled and subjected to temperatures of from about 950° C. to about 1050° C. at pressures of only from about 1 to about 2 ksi for a duration of from about 1 to about 5 hours to achieve a substantially complete bond of about 100%. This is in strong contrast to the conventional pressures called for in known methods, whereby pressures in excess of 4 ksi are used.

For some applications, in accordance with embodiments of the present invention, small or specified average grain size of from about 1 μm to about 100 μm is required of the powder. To avoid grain growth during the bonding procedures, a second metal powder optionally may be mixed in with the aluminum or copper powder. In the case of the aluminum powder, a desired amount of zinc powder may be added.

The metal powder serves to foster formation of a metal alloy during bonding due to inter-diffusion between the metal powder and the adjacent backing plate and target metals. Such alloys typically exhibit a lower melting point than the base metal, and, therefore, the bonding temperatures required are also typically lower, resulting in another improvement over known bonding protocols. For example, using a Zn/30 wt % Al mixed powder as a bond medium to bond fine grain titanium (<15 μm) to an aluminum backing plate, a 100% bond can be achieved at 450° C. without increasing the target grain size. The percentage of bonding is determined using an ultrasonic instrument as would be understood by one skilled in the field. The existence of voids or separations at the bonding interface will show irregular reflection of intensity.

As is well known in the prior art, one or more of the adjacent surfaces of the backing plate and target are extensively machined in time-consuming fashion to facilitate bonding. Such machining refers to the creation of ridges, grooves, etc. in the surfaces being bonded. By contrast, the surfaces to be bonded according to embodiments of the present invention are not subjected to rigorous pre-conditioning, but, instead may merely be roughened by grit-blasting or other roughening methods to achieve a bond surface roughness of from about 150 Ra to about 250 Ra, preferably from about 200 Ra to about 250 Ra, as would be understood by one skilled in the field.

The preferred bond methods of the present invention are preferably performed using a vacuum hot press under vacuum of greater than about 10E-4 Torr and applied pressure greater than about 0.5 ksi (0.35 kg/mm²) and less than about 2 ksi. The interlayer formed by the consolidation of powder is controlled to a minimum thickness of about 30 μm. Conventionally, a graphite punch is used in conjunction with a vacuum hot press arrangement. The flexural strength of graphite is about 6 ksi. Due to safety and other concerns, the maximum pressure recommended in connection with the preferred embodiments of the present invention is about 3 ksi. Higher pressure can be applied using other punch materials, such as alloy steels. As would be understood, the higher the applied pressure, the shorter the required bonding time. When a pressure of 2 ksi is applied, a holding time duration of from about 2 to about 3 hours is particularly preferred. This results in one advantage of the present invention, as a lower pressure (from about 0.5 ksi to about 2.0 ksi) is required to achieve substantially 100% bonding. It is understood that, even within the stated preferred pressure range, the higher the bonding pressure, the shorter the required bonding time.

The preferred thickness of the interlayer after the powder is consolidated to a minimum of about 30 μm. Ideally, the packing density of the powder is from about 30% to about 40%. Therefore, the preferred minimum thickness of the powder prior to packing, or consolidating is about 90 μm. It has now been discovered that the preferred interlayer thickness is from about 30 μm to about 1000 μm. An interlayer thickness of less than 30 μm may generate fracture due to exceeding the maximum elongation of the interlayer material during cooling of the bonding process. Such induced elongation induces stress due to the difference in thermal shrinkage properties between the target material and the backing plate material. Additionally, interlayers exceeding 1000 μm are thought to require longer bonding time, and offer no recognized or perceived advantage in bonding integrity.

The bond strength achieved according to methods of the present invention is at least equivalent (about 100%) to that achieved by more expensive, cumbersome and time-consuming methods. In other words, known methods use increased temperature, pressure, or both, (such as those used in hot-isostatic pressing), greatly increasing the complexity, hazard and cost of such known systems in comparison to the greater economical efficiency afforded by the methods of the present invention.

As stated above, the known methods for bonding backing plates to targets require higher temperatures, higher pressure, significantly machined surfaces, or the inclusion of discrete metallic interlayers. The methods of the present invention afford a product target made according to far more efficient methods in terms of materials, cost and time.

As stated above, the present invention employs a layer or section of metal or metal alloy powder interposed between the target material and the backing plate as a media to facilitate their bonding. The advance is achieved without the known use of foil interlayers, extreme roughening of either of the facing surfaces of the target and/or backing layer, or manufactured relief or projections, patterns, drillings etc. in the surfaces. The bonding is able to occur at lower pressures with substantially 100% bonding achieved.

### EXAMPLES

### Example 1

A 4.5 inch diameter×0.25 inch thickness Ta target was bonded to a 5 inch diameter×0.5 inch thick Al 6061 alloy backing plate with a 4.52 inch diameter×0.15″ deep recess. Both the target and backing plate bond surfaces were grit-blasted by SiC to create a surface roughness about 200 Ra. An amount of 8 grams of 20 μm Al powder was placed on the recess surface of the backing plate to form uniform powder layer followed by the placement of target with the grit-blasted size contacting to the powder layer. The assembly was positioned in a vacuum hot press. The assembly was pressed at 600° C./2 ksi for 3 hours under 10E-5 Torr vacuum. The pressed assembly was 100% bonded. The thickness of the interlayer was 300 μm. By applying the bond failure test of commonly-owned U.S. Pat. No. 6,092,427, the entire contents of which are incorporated by reference herein as if made a part of the present specification, the required force to separate the bond assembly with 1 inch wide was 2300 pounds, which was about 7 times greater than that of the 60Pb-40Sn solder bond. The tensile strength of 60Pb-40Sn solder is about 5.4 ksi. It is estimated that the bond strength of Ta to Al 6061 with Al powder medium is about 38 ksi. See FIG. 2.

### Example 2

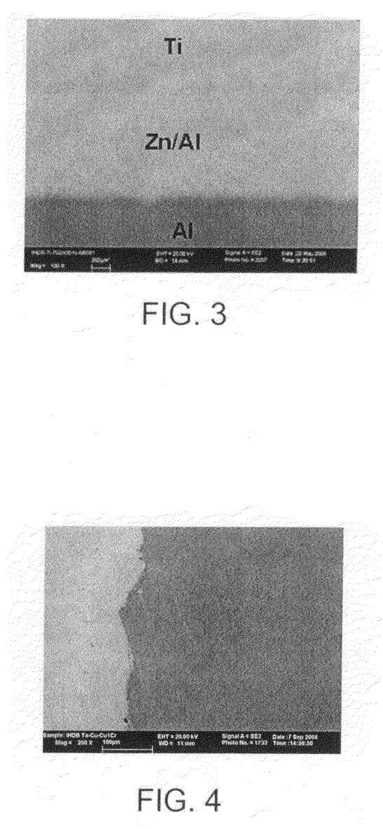

A 4.50 inch diameter×0.25 inch thickness Ti target was bonded to a 5 inch diameter×0.5 inch thickness Al 6061 alloy backing plate with a 4.52 inch diameter×0.15″ deep recess. The grain size of the Ti was 11 μm average. Both the target and backing plate bond surfaces were grit-blasted by SiC to create a surface roughness about 200 Ra. An amount of 38 grams of 20 μm average Zn-30 wt % Al powder was positioned on the recess surface of the backing plate to form uniform powder layer, followed by the placement of target with the grit-blasted size contacting the powder layer. The assembly was positioned within a vacuum hot press. The assembly was pressed at 450° C./2 ksi for 3 hours under 5×10E-5 Torr vacuum. The pressed assembly was 100% bonded. The average grain size was 11 μm. The thickness of the interlayer was 600 μm. The bond failure test of U.S. Pat. No. 6,092,427 was used, and the required force to separate the bond assembly with 1 inch wide was 840 pounds. This was about 2.5 times greater than that of the 60Pb-40Sn solder bond. It is estimated that the bond strength of Ti to Al 6061 with Zn-30 wt % powder medium is about 13 ksi. See FIG. 3.

### Example 3

A 4.5 inch diameter×0.25 inch thickness Ta target was bonded to a 5 inch diameter×0.5 inch thick Cu 182 alloy (Cu-1Cr) backing plate with a 4.52 inch diameter×0.15″ deep recess. Both the target and backing plate bond surfaces were grit-blasted by SiC to create a surface roughness about 250 Ra. An amount of 18 grams of 30 μm Cu powder was placed on the recess surface of the backing plate to form uniform powder layer followed by the placement of target with the grit-blasted size contacting to the powder layer. The assembly was positioned within a vacuum hot press. The assembly was pressed at 1000° C./2 ksi for 3 hours under 5×10E-5 Torr vacuum. The pressed assembly was 100% bond. The thickness of the interlayer was 200 μm. By applying the bond failure test of U.S. Pat. No. 6,092,427, the required force to separate the bond assembly with 1 inch wide was 1080 pounds, which was about 3 times greater than that of the 60Pb-40Sn solder bond. It is estimated that the bond strength of Ta to Cu 182 with Cu powder medium is about 17 ksi. See FIG. 4.

While the invention has been described in detail with reference to specific embodiments thereof, it will be apparent to one skilled in the field that various changes, modifications and substitutions can be made, and equivalents employed without departing from, and are intended to be included within, the scope of the claims.

We claim:

1. A method for manufacturing a sputtering target assembly comprising the steps of:
providing a metallic backing plate having a first surface;
providing a metallic target material having a first surface;
providing a metallic powder;
interposing a pre-determined amount of metallic powder at a pre-determined thickness of from about 30 μm to about 1000 μm between the first surface of the target material and the first surface of the backing plate to achieve an assembly; and
subjecting the assembly to a predetermined pressure of from about 0.5 to about 2 ksi and predetermined temperature adequate to soften the powder and substantially uniformly bond the backing plate to the target material.

2. The method of claim 1, wherein the assembly is subjected to a vacuum hot press.

3. The method of claim 2, wherein the pressure is maintained at a pressure of about 2 ksi.

4. The method of claim 1, wherein the metallic powder is a metal alloy powder.

5. The method of claim 1, wherein the metallic powder is selected from the group consisting of aluminum powder and copper powder.

6. The method of claim 1, wherein the metallic powder further comprises a dopant.

7. The method of claim 6, wherein the dopant is a zinc powder.

8. The method of claim 1, wherein the backing plate is substantially 100% bonded to the target material.

9. The method of claim 1, wherein the powder has a grain size of from about 1 μm to about 100 μm.

10. The method of claim 1, wherein the first surface of the target material and/or the first surface of the backing plate are treated to achieve a surface roughness of from about 150 Ra to about 250 Ra.

11. The method of claim 1, wherein the metallic powder is selected from the group consisting of: aluminum metallic powder and aluminum alloy powder; said backing plate is made from aluminum; and the target material is selected from the group consisting of: tungsten, titanium, tantalum, copper, nickel, cobalt, chromium and aluminum.

12. The method of claim 1, wherein the metallic powder is selected from the group consisting of: copper metallic powder and copper alloy powder; said backing plate is made from copper; and the target material is selected from the group consisting of: tungsten, titanium, tantalum, copper, nickel, cobalt, chromium and aluminum.

13. The method of claim 11, wherein the assembly is maintained at a temperature in the range of from about 550° C. to about 650° C. for a duration of from about 1 to about 5 hours.

14. The method of claim 12, wherein the assembly is maintained at a temperature in the range of from about 960° C. to about 1050° C. for a duration of from about 1 to about 5 hours.

15. A sputtering target assembly made according to the method of claim 1.

16. A sputtering target assembly made according to the method of claim 11.

17. A sputtering target assembly made according to the method of claim 12.

18. A plasma discharge assembly comprising a sputtering target made according to the method of claim 1.

19. A plasma discharge assembly comprising a sputtering target made according to the method of claim 11.

20. A plasma discharge assembly comprising a sputtering target made according to the method of claim 12.
